(19) United States
(12) Patent Application Publication
(10) Pub. No.: US 2019/0229070 A1
(43) Pub. Date: Jul. 25, 2019

(54) FAN-OUT SEMICONDUCTOR PACKAGE

(71) Applicant: SAMSUNG ELECTRO-MECHANICS CO., LTD., Suwon-si (KR)

(72) Inventors: Yi Eok KWON, Suwon-si (KR); Jae Ean LEE, Suwon-si (KR); Hak Young LEE, Suwon-si (KR)

(21) Appl. No.: 16/105,956

(22) Filed: Aug. 20, 2018

(30) Foreign Application Priority Data
Jan. 19, 2018 (KR) 10-2018-0007331

(51) Int. Cl. H01L 23/00; H01L 23/31; H01L 23/498; H01L 23/367; H01L 25/065

(52) U.S. Cl. CPC H01L 23/562; H01L 23/3128; H01L 23/49822; H01L 25/0655; H01L 23/49827; H01L 23/367; H01L 23/49816

(57) ABSTRACT

A fan-out semiconductor package includes: a semiconductor chip; a redistribution portion disposed below the semiconductor chip; a reinforcing member disposed on the redistribution portion and surrounding the semiconductor chip; and an encapsulant disposed on the redistribution portion to embed the semiconductor chip and the reinforcing member therein.

### CROSS-REFERENCE TO RELATED APPLICATION(S)

This application claims benefit of priority to Korean Patent Application No. 10-2018-0007331 filed on Jan. 19, 2018 in the Korean Intellectual Property Office, the disclosure of which is incorporated herein by reference in its entirety.

### TECHNICAL FIELD

The present disclosure relates to a fan-out semiconductor package.

### BACKGROUND

Recently, a manufacturing method of using an Integrated Fan-Out wafer-level package (Info-WLP) in developing application processors (APs) of next generation smartphones has been used.

In addition, in the future it is expected that a side by side (die-to-die) structure in a package-of-package (PoP) structure will be adopted in order transmit larger amounts of data. In addition, for the purpose of a high data rate (HDR), it is expected that high performance computing (HPC), network, and graphic card markets using a high bandwidth memory (HBM) will be expanded.

Recently, a high bandwidth memory (HBM) using a silicon (Si) interposer has been used in graphic and field programmable gate array (FPGA) markets, and a high specification second-generation high bandwidth memory (HBM2) has been used. This technology requires die-to-die interconnection technology, and expensive silicon (Si) interposer technology using semiconductor technology has been used.

Further, it is requisite to control warpage in order to implement a chip-last method, and thus, there is a need to develop a structure capable of preventing warpage.

### SUMMARY

An aspect of the present disclosure may provide a fan-out semiconductor package in which warpage of a redistribution portion may be decreased and a heat dissipation effect may be improved.

According to an aspect of the present disclosure, a fan-out semiconductor package may include: a first semiconductor chip; a redistribution portion disposed below the semiconductor chip; a reinforcing member disposed on the redistribution portion and surrounding the first semiconductor chip; and an encapsulant disposed on the redistribution portion to embed the first semiconductor chip and the reinforcing member therein.

The reinforcing member may include sections each having a bar shape and spaced apart from each other, and the sections of the reinforcing member may be disposed at edges of the redistribution portion, respectively.

The reinforcing member may include at least one selected from the group consisting of silver (Ag), palladium (Pd), aluminum (Al), nickel (Ni), titanium (Ti), gold (Au), copper (Cu), and platinum (Pt), or mixtures thereof.

The redistribution portion may include an insulating layer and at least one conductor layer disposed in the insulating layer.

The redistribution portion may further include an underfill disposed on an upper surface of the insulating layer and a passivation layer disposed on a lower surface of the insulating layer.

The underfill may be disposed inwardly of the reinforcing member, and the encapsulant may be disposed outwardly of the reinforcing member.

The underfill may be in contact with the insulating layer of the redistribution portion disposed inwardly of the reinforcing member, and the encapsulant may be in contact with a portion of the insulating layer of the redistribution portion disposed outwardly of the reinforcing member.

The conductor layer may include a wiring portion having at least one layer and a lower surface electrode exposed to a lower surface of the passivation layer.

The fan-out semiconductor package may further include an electrical connection structure connected to the lower surface electrode.

The reinforcing member may be connected to the conductor layer.

The reinforcing member may not be electrically connected to the redistribution portion.

The fan-out semiconductor package may further include a connection via having one end connected to the reinforcing member and the other end exposed to an upper surface of the encapsulant and a heat dissipation member connected to the connection via and covering the upper surface of the encapsulant.

A lower surface of the heat dissipation member may be in contact with an upper surface of the semiconductor chip.

The connection via and the heat dissipation member may be made of the same material as that of the reinforcing member.

The connection via may have a bar shape corresponding to that of the reinforcing member.

The fan-out semiconductor package of may further includes: a plurality of connection vias each having one end connected to the reinforcing member and the other end exposed to an upper surface of the encapsulant, disposed on the reinforcing member to be spaced apart from each other, and each having a pillar shape; and a heat dissipation member connected to the plurality of connection vias and covering the upper surface of the encapsulant.

The fan-out semiconductor package may further include a second semiconductor chip disposed side by side with the first semiconductor chip in a horizontal direction. The reinforcing member may surround the second semiconductor chip, and the encapsulant may embed the second semiconductor chip.

According to another aspect of the present disclosure, a fan-out semiconductor package may include: a redistribution portion; a first semiconductor chip disposed on an upper surface of the redistribution portion; a reinforcing member disposed at an edge of the redistribution portion; an encapsulant disposed on the redistribution portion, an upper surface of the first semiconductor chip being exposed from the encapsulant and the reinforcing member being embedded in the encapsulant; a connection via connected to the reinforcing member and having one end exposed to an upper surface of the encapsulant; and a heat dissipation member connected to the connection via and covering the encapsulant to be in contact with the upper surface of the first semiconductor chip.

The fan-out semiconductor package may further include a second semiconductor chip disposed side by side with the first semiconductor chip on the upper surface of the redistribution portion. An upper surface of the second semiconductor chip may be exposed from the encapsulant, and the heat dissipation member may be in contact with the upper surface of the second semiconductor chip.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is ultimately mounted on a mainboard of an electronic device;

FIG. 6 is a schematic cross-sectional view illustrating a case in which a fan-in semiconductor package is embedded in an interposer substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating a fan-out semiconductor package according to a first exemplary embodiment in the present disclosure;

FIG. 10 is a schematic plan view illustrating the fan-out semiconductor package according to a first exemplary embodiment in the present disclosure;

FIG. 11 is a schematic cross-sectional view illustrating a fan-out semiconductor package according to a second exemplary embodiment in the present disclosure;

FIG. 12 is a schematic exploded perspective view illustrating a fan-out semiconductor package according to a second exemplary embodiment in the present disclosure;

FIG. 13 is a view illustrating a first modified example of connection vias; and

FIG. 14 is a schematic cross-sectional view illustrating a fan-out semiconductor package according to a fourth exemplary embodiment in the present disclosure.

### DETAILED DESCRIPTION

Hereinafter, exemplary embodiments of the present disclosure will now be described in detail with reference to the accompanying drawings.

Electronic Device

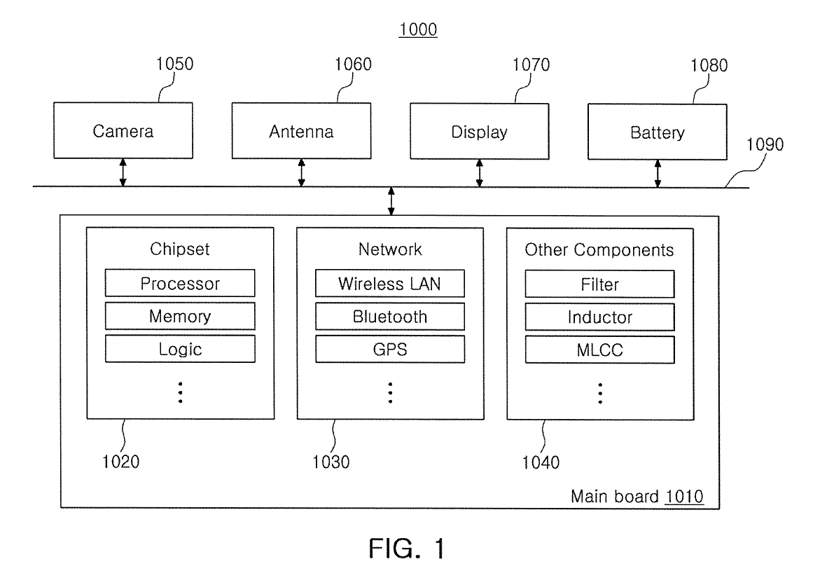

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

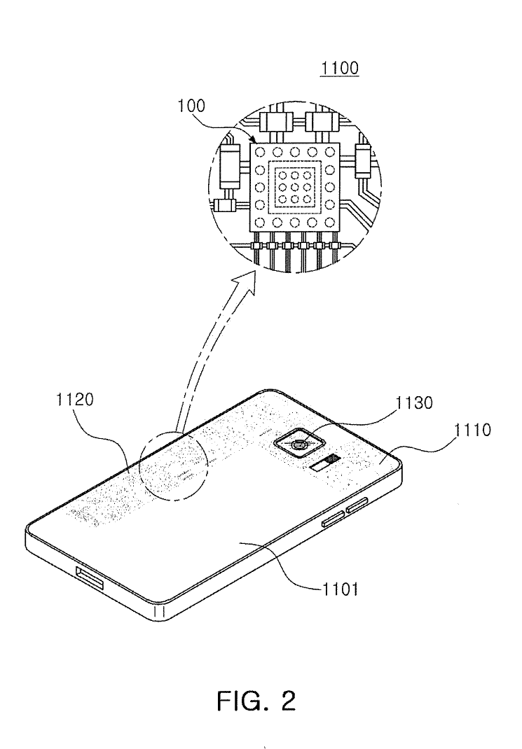

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the mainboard 1010, such as a camera module 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

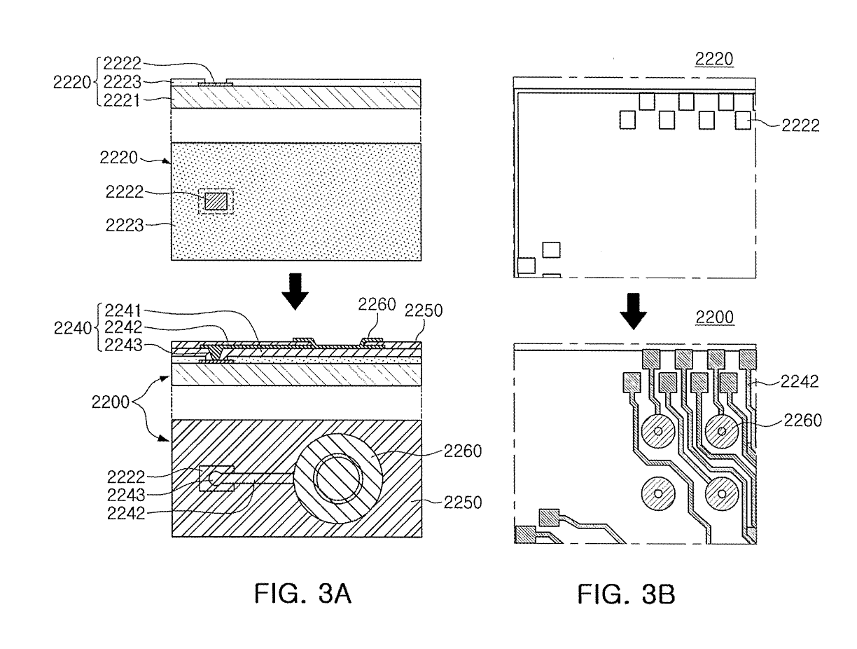

FIGS. 3A and 3B are schematic cross-sectional views illustrating states of a fan-in semiconductor package before and after being packaged.

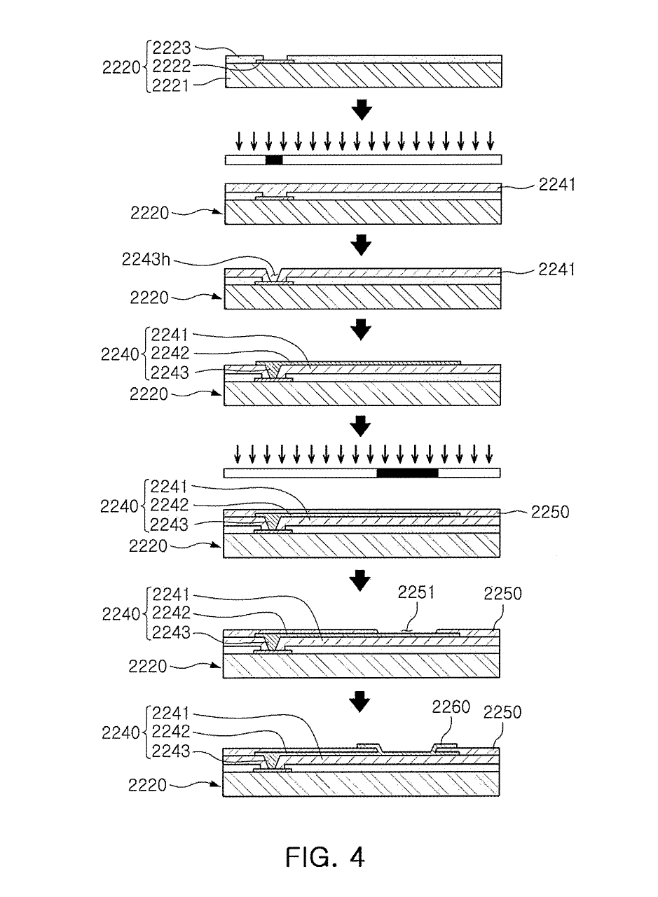

FIG. 4 is schematic cross-sectional views illustrating a packaging process of a fan-in semiconductor package.

Referring to FIGS. 3A through 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in electronic component package on the mainboard of the electronic device.

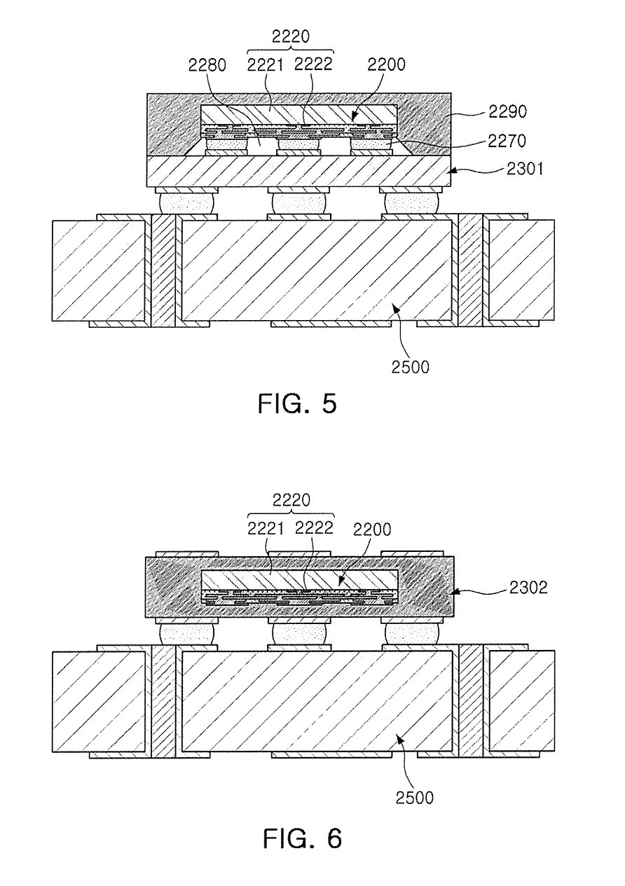

FIG. 5 is a schematic cross-sectional view illustrating a case in which a fan-in semiconductor package is mounted on an interposer substrate and is ultimately mounted on a mainboard of an electronic device.

FIG. 6 is a schematic cross-sectional view illustrating a case in which a fan-in semiconductor package is embedded in an interposer substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through an interposer substrate 2301, and the fan-in semiconductor package 2200 may be ultimately mounted on a mainboard 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate interposer substrate and be then mounted on the mainboard of the electronic device through a packaging process or may be mounted and used on the mainboard of the electronic device in a state in which it is embedded in the interposer substrate.

Fan-Out Semiconductor Package

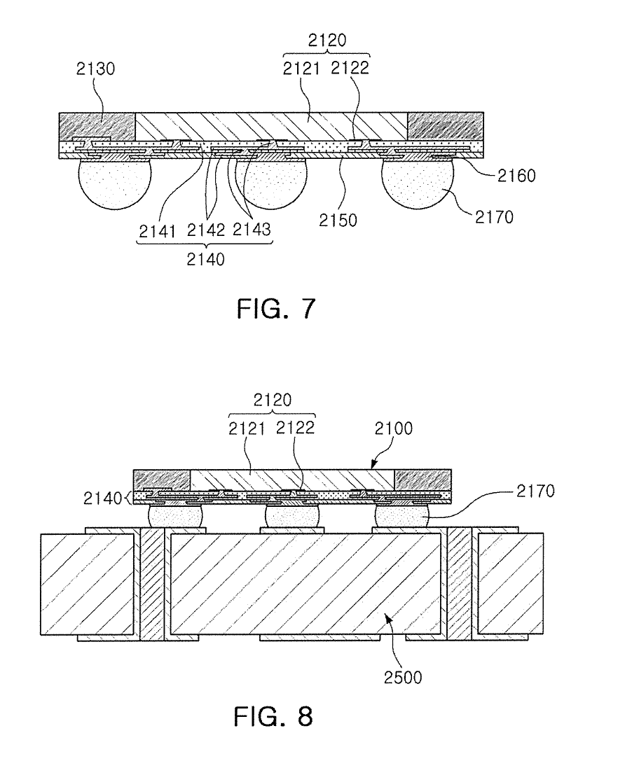

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case that a size of the semiconductor chip is decreased, a standardized ball layout may be used in the fan-out semiconductor package as it is, such that the fan-out semiconductor package may be mounted on the mainboard of the electronic device without using a separate interposer substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

Fan-out semiconductor packages according to exemplary embodiments in the present disclosure will hereinafter be described with reference to the drawings.

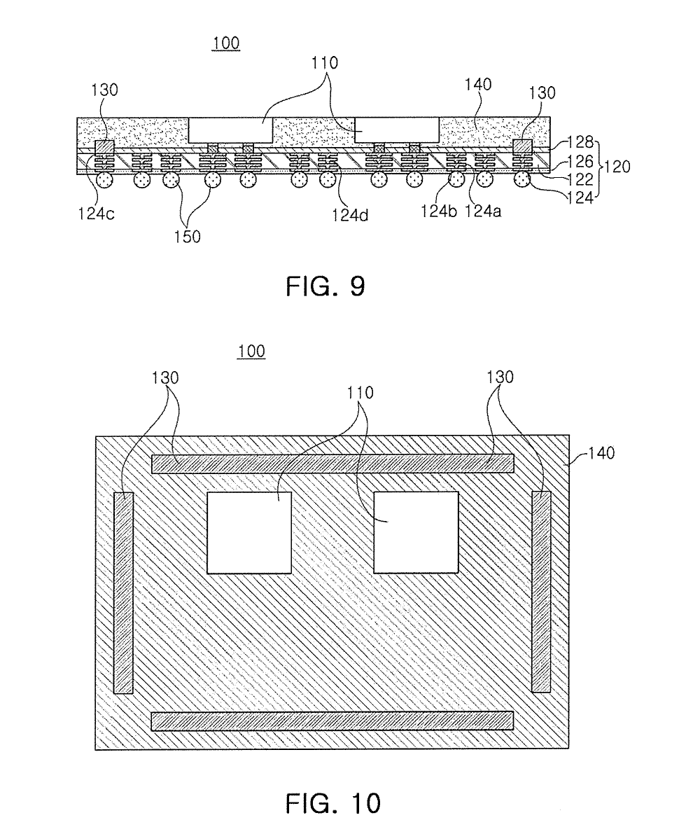

FIG. 9 is a schematic cross-sectional view illustrating a fan-out semiconductor package according to a first exemplary embodiment in the present disclosure, and FIG. 10 is a schematic plan view illustrating the fan-out semiconductor package according to a first exemplary embodiment in the present disclosure.

Referring to FIGS. 9 and 10, a fan-out semiconductor package 100 according to a first exemplary embodiment in the present disclosure may include semiconductor chips 110, a redistribution portion 120, reinforcing members 130, and an encapsulant 140 as an example.

A plurality of semiconductor chips 110 may be disposed to be spaced apart from each other, and be disposed side by side in a horizontal direction on the redistribution portion 120. As an example, each of the semiconductor chips 110 may be an integrated circuit (IC) provided in an amount of several hundred to several million or more elements integrated in a single chip. In this case, the IC may be, for example, a processor chip (more specifically, an application processor (AP)) such as a central processor (for example, a CPU), a graphic processor (for example, a GPU), a field programmable gate array (FPGA), a digital signal processor, a cryptographic processor, a micro processor, a micro controller, or the like, but is not limited thereto. That is, the IC may be a logic chip such as an analog-to-digital converter, an application-specific IC (ASIC), or the like, or a memory chip such as a volatile memory (for example, a DRAM), a non-volatile memory (for example, a ROM), a flash memory, or the like. In addition, the abovementioned elements may also be combined with each other and be disposed. The number of the semiconductor chip (s) 110 may two as shown in the drawings, and be one or more two.

In addition, the semiconductor chip 110 may be formed on the basis of an active wafer. In this case, a base material of a body of the semiconductor chip 110 may be silicon (Si), germanium (Ge), gallium arsenide (GaAs), or the like. Various circuits may be formed on the body. Connection pads may electrically connect the semiconductor chip 110 to other components. A material of each of the connection pads may be a conductive material such as aluminum (Al), or the like. The semiconductor chip 110 may be a bare die, a redistribution layer (not illustrated) may further be formed on the active surface of the semiconductor chip 110, if necessary, and bumps (not illustrated), or the like, may be connected to the connection pads.

In addition, the semiconductor chips 110 may be electrically connected to the redistribution portions 120 by flip-chip bonding.

Meanwhile, a case in which two semiconductor chips 110 are mounted on the redistribution portion 120 is illustrated by way of example in the present exemplary embodiment, the number of semiconductor chips 110 is not limited thereto, but may be variously modified, if necessary.

In addition, the semiconductor chips 110 may be mounted on the redistribution portion 120 after the encapsulant 140 is formed. That is, the semiconductor chips 110 may be mounted on the redistribution portion 120 by a chip-last method.

As an example, an upper surface of each of the semiconductor chips 110 may be exposed from an upper surface of the encapsulant 140. Therefore, heat generated from the semiconductor chip 110 may be more easily dissipated externally. However, the semiconductor chips 110 are not limited thereto, but may also be entirely embedded in the encapsulant 140.

The redistribution portion 120 may be disposed below the semiconductor chips 110. As an example, the redistribution portion 120 may include an insulating layer 122, at least one conductor layer 124 formed in the insulating layer 122, a passivation layer 126 formed on a lower surface of the insulating layer 122, and an underfill 128 formed on an upper surface of the insulating layer 122.

Meanwhile, the conductor layer 124 may include wiring portions 124a formed by copper (Cu) plating, lower surface electrodes 124b exposed to a lower surface of the passivation layer 126 and formed by nickel-copper plating, connection pads 124c exposed to an upper surface of the underfill 128 and connected to reinforcing members 130 to be described below, and vias 124d connecting the wiring portions 124a to each other.

In addition, a material of the passivation layer 126 is not particularly limited. For example, an insulating material may be used as the material of the passivation layer 126. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a solder resist may also be used. In addition, exposing holes for exposing the lower surface electrodes 124b may be formed in the passivation layer 126.

The underfill 128 may be formed after the semiconductor chips 110 are mounted by the chip-last method. As an example, an insulating material may be used as a material of the underfill 128. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like.

The reinforcing members 130 may be connected to the redistribution portion 120 to be disposed outside of the plurality of semiconductor chips 110. As an example, a plurality of reinforcing members 130 may have a bar shape, and may be disposed to be spaced apart from each other. In addition, the reinforcing members 130 may be disposed at, for example, edges of the redistribution portion 120, and may be disposed to have a substantially rectangular shape. The plurality of reinforcing members 130 may be spaced apart from each other in corner portions of the fan-out semiconductor package 100.

In addition, the reinforcing members 130 may be connected to the conductor layer 124 of the redistribution portion 120. Meanwhile, the reinforcing members 130 may include at least one selected from the group consisting of silver (Ag), palladium (Pd), aluminum (Al), nickel (Ni), titanium (Ti), gold (Au), copper (Cu), and platinum (Pt), or mixtures thereof, and may be formed by plating. In addition, a cross section of each of the reinforcing members 130 may have a rectangular shape.

As described above, the plurality of reinforcing members 130 may be disposed at the edges of the redistribution portion 120 and may have the bar shape, and generation of warpage of the redistribution portion 120 in the subsequent process may thus be prevented.

Further, when the encapsulant 140 is formed after the reinforcing members 130 are formed, the reinforcing members 130 may serve as a dam suppressing a flow of the encapsulant 140.

In addition, the reinforcing members 130 may be connected to the conductor layer 124 to dissipate heat. Therefore, a heat dissipation effect may be improved.

In addition, since the reinforcing members 130 are formed on the connection pads 124c, the reinforcing members 130 may serve to prevent the underfill 128 from being bled at the time of forming the underfill 128.

The encapsulant 140 may be disposed on the redistribution portion 120 to embed the plurality of semiconductor chips 110 and the reinforcing members 130 therein. A material of the encapsulant 140 is not particularly limited. For example, an insulating material may be used as the material of the encapsulant 140. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a PID resin may also be used as the insulating material.

As an example, the encapsulant 140 may have a thickness at which upper surfaces of the semiconductor chips 110 are externally exposed.

Electrical connection structures 150 may physically or electrically externally connect the fan-out semiconductor package 100. For example, the fan-out semiconductor package 100 may be mounted on the mainboard of the electronic device through the electrical connection structures 150. Each of the electrical connection structures 150 may be formed of a conductive material, for example, a solder, or the like. However, this is only an example, and a material of each of the electrical connection structures 150 is not particularly limited thereto. Each of the electrical connection structures 150 may be a land, a ball, a pin, or the like. The electrical connection structures 150 may be formed as a multilayer or single layer structure. When the electrical connection structures 150 are formed as a multilayer structure, the electrical connection structures 150 may include a copper (Cu) pillar and a solder. When the electrical connection structures 150 are formed as a single layer structure, the electrical connection structures 150 may include a tin-silver solder or copper (Cu). However, this is only an example, and the electrical connection structures 150 are not limited thereto.

As described above, the generation of the warpage of the redistribution portion 120 may be prevented by the reinforcing members 130.

In addition, the reinforcing members 130 may serve as the dam suppressing the flow of the underfill 128 to prevent the underfill 128 from being bled.

Further, heat dissipation efficiency may be improved through the reinforcing members 130.

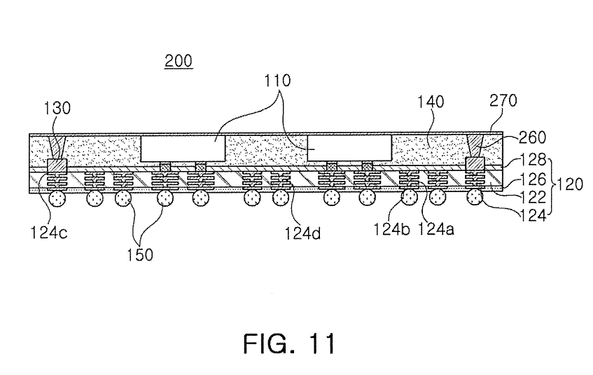

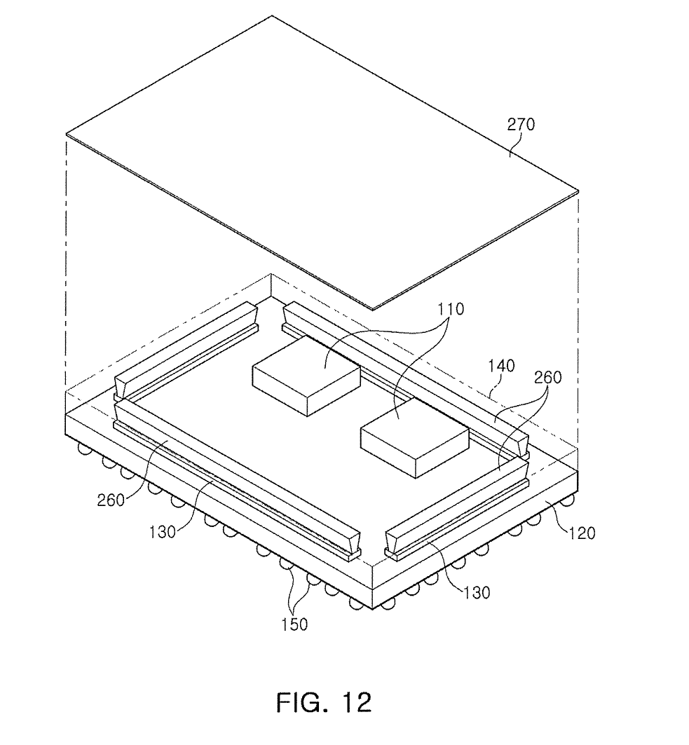

FIG. 11 is a schematic cross-sectional view illustrating a fan-out semiconductor package according to a second exemplary embodiment in the present disclosure, and FIG. 12 is a schematic exploded perspective view illustrating a fan-out semiconductor package according to a second exemplary embodiment in the present disclosure.

Referring to FIGS. 11 and 12, a fan-out semiconductor package 200 according to a second exemplary embodiment in the present disclosure may include semiconductor chips 110, a redistribution portion 120, reinforcing members 130, an encapsulant 140, connection vias 260, and a heat dissipation member 270 as an example.

Meanwhile, since the semiconductor chips 110, the redistribution portion 120, the reinforcing members 130, and the encapsulant 140 are the same components as those described above, a detailed description therefor is omitted and is replaced by the abovementioned description.

Each of the connection vias 260 may be disposed so that one end thereof is connected to the reinforcing member 130 and the other end thereof is exposed to an upper surface of the encapsulant 140. The connection via 260 may have a bar shape corresponding to that of the reinforcing member 130. That is, the connection via 260 may have a substantially rectangular shape when viewed from the top. In addition, a cross section of the connection via 260 may be tapered. That is, the connection via 260 may have a taper shape of which an upper portion has a width greater than that of a lower portion.

As an example, the connection via 260 may be formed of a conductive material, similar to the reinforcing member 130. That is, the connection via 260 may include at least one selected from the group consisting of silver (Ag), palladium (Pd), aluminum (Al), nickel (Ni), titanium (Ti), gold (Au), copper (Cu), and platinum (Pt), or mixtures thereof, as an example.

Meanwhile, the connection vias 260 may serve to prevent warpage of the redistribution portion 120 together with the reinforcing members 130. That is, strength of the redistribution portion 120 may be reinforced by the connection vias 260, such that generation the warpage in the redistribution portion 120 may be decreased.

In addition, the connection vias 260 may be connected to the reinforcing members 130 to be provided as heat dissipation paths, and may thus serve to improve heat dissipation efficiency.

The heat dissipation member 270 may be connected to the connection vias 260, and may cover the upper surface of the encapsulant 140. As an example, the heat dissipation member 270 may be disposed so that a lower surface thereof is in contact with an upper surface of the semiconductor chip 110. However, the heat dissipation member 270 is not limited thereto, but may also be disposed so that the lower surface thereof is spaced apart from the upper surface of the semiconductor chip 110.

In addition, the heat dissipation member 270 may have a rectangular plate shape.

Meanwhile, the heat dissipation member 270 may be formed of a conductive material, similar to the connection via 260. That is, the heat dissipation member 270 may include at least one selected from the group consisting of silver (Ag), palladium (Pd), aluminum (Al), nickel (Ni), titanium (Ti), gold (Au), copper (Cu), and platinum (Pt), or mixtures thereof, as an example.

As described above, the heat dissipation member 270 may be connected to the connection vias 260, and the heat dissipation efficiency may thus be further improved.

As described above, the warpage of the redistribution portion 120 may further be decreased through the connection vias 260. That is, the connection vias 260 may prevent the generation of the warpage of the redistribution portion 120 together with the reinforcing members 130, and the warpage of the redistribution portion 120 may thus be further decreased.

Further, the heat dissipation efficiency may be improved through the connection vias 260 and the heat dissipation member 270.

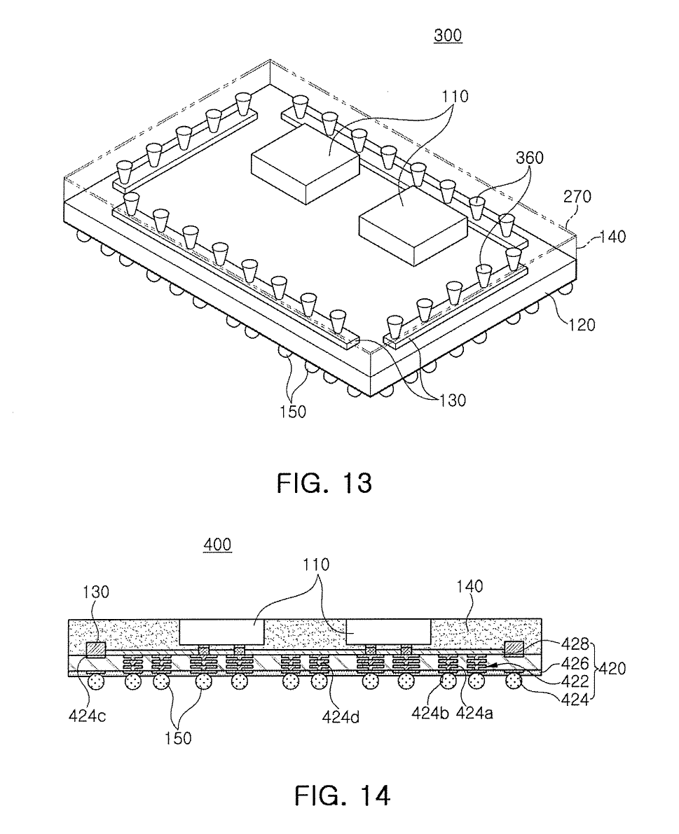

FIG. 13 is a view illustrating a first modified example of connection vias.

Referring to FIG. 13, a fan-out semiconductor package 300 according to a third exemplary embodiment in the present disclosure may include semiconductor chips 110, a redistribution portion 120, reinforcing members 130, an encapsulant 140, connection vias 360, and a heat dissipation member 270 as an example.

Meanwhile, since the semiconductor chips 110, the redistribution portion 120, the reinforcing members 130, the encapsulant 140, and the heat dissipation member 270 are substantially the same as those described above, a detailed description therefor is omitted and is replaced by the abovementioned description.

A plurality of connection vias 360 may have one ends connected to the reinforcing members 130, may be disposed on the reinforcing members 130 to be spaced apart from each other, and may have a pillar shape.

As described above, the plurality of connection vias 360 may have the pillar shape and be disposed on the reinforcing members 130 to be spaced apart from each other, and may thus be more easily formed.

FIG. 14 is a schematic cross-sectional view illustrating a fan-out semiconductor package according to a fourth exemplary embodiment in the present disclosure.

Referring to FIG. 14, a fan-out semiconductor package 400 according to a fourth exemplary embodiment in the present disclosure may include semiconductor chips 110, a redistribution portion 420, reinforcing members 130, and an encapsulant 140 as an example.

Meanwhile, since the semiconductor chips 110, the reinforcing members 130, and the encapsulant 140 are the same components as those described above, a detailed description therefor is omitted and is replaced by the abovementioned description.

The redistribution portion 420 may be disposed below the semiconductor chips 110. As an example, the redistribution portion 420 may include an insulating layer 422, at least one conductor layer 424 formed in the insulating layer 422, a passivation layer 426 formed on a lower surface of the insulating layer 422, and an underfill 428 formed on an upper surface of the insulating layer 422.

Meanwhile, the conductor layer 424 may include wiring portions 424a formed by copper (Cu) plating, lower surface electrodes 424b exposed to a lower surface of the passivation layer 426 and formed by nickel-copper plating, connection pads 424c exposed to an upper surface of the underfill 428 and connected to reinforcing members 130 to be described below, and vias 424d connecting the wiring portions 424a to each other.

In addition, a material of the passivation layer 426 is not particularly limited. For example, an insulating material may be used as the material of the passivation layer 426. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a solder resist may also be used. In addition, exposing holes for exposing the lower surface electrodes 424b may be formed in the passivation layer 426.

The underfill 428 may be formed after the semiconductor chips 110 are mounted by the chip-last method. As an example, an insulating material may be used as a material of the underfill 428. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, (BT, or the like.

As an example, the underfill 428 may be disposed in only an inner region of the reinforcing members 130. In addition, outwardly of the reinforcing members 130, the encapsulant 140 may be in contact with an upper surface of the redistribution portion 420.

In addition, the reinforcing members 130 may not be electrically connected to the redistribution portion 420. That is, the connection pads 424c of the redistribution portion 420 may not be connected to the wiring portions 424a.

As set forth above, according to an exemplary embodiment in the present disclosure, the warpage of the redistribution portion may be decreased, and the heat dissipation effect may be improved.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a first semiconductor chip;
a redistribution portion disposed below the semiconductor chip;
a reinforcing member disposed on the redistribution portion and surrounding the semiconductor chip; and
an encapsulant disposed on the redistribution portion to embed the semiconductor chip and the reinforcing member therein.

2. The fan-out semiconductor package of claim 1, wherein the reinforcing member includes sections each having a bar shape and spaced apart from each other, and
the sections of the reinforcing member are disposed at edges of the redistribution portion, respectively.

3. The fan-out semiconductor package of claim 1, wherein the reinforcing member includes at least one selected from the group consisting of silver (Ag), palladium (Pd), aluminum (Al), nickel (Ni), titanium (Ti), gold (Au), copper (Cu), and platinum (Pt), or mixtures thereof.

4. The fan-out semiconductor package of claim 1, wherein the redistribution portion includes an insulating layer and at least one conductor layer disposed in the insulating layer.

5. The fan-out semiconductor package of claim 4, wherein the redistribution portion further includes an underfill disposed on an upper surface of the insulating layer and a passivation layer disposed on a lower surface of the insulating layer.

6. The fan-out semiconductor package of claim 5, wherein the underfill is disposed inwardly of the reinforcing member, and the encapsulant is disposed outwardly of the reinforcing member.

7. The fan-out semiconductor package of claim 6, wherein, the underfill is in contact with the insulating layer of the redistribution portion disposed inwardly of the reinforcing member, and
the encapsulant is in contact with a portion of the insulating layer of the redistribution portion disposed outwardly of the reinforcing member.

8. The fan-out semiconductor package of claim 5, wherein the conductor layer includes a wiring portion having at least one layer and a lower surface electrode exposed to a lower surface of the passivation layer.

9. The fan-out semiconductor package of claim 8, further comprising an electrical connection structure connected to the lower surface electrode.

10. The fan-out semiconductor package of claim 4, wherein the reinforcing member is connected to the conductor layer.

11. The fan-out semiconductor package of claim 1, wherein the reinforcing member is not electrically connected to the redistribution portion.

12. The fan-out semiconductor package of claim 1, further comprising:
a connection via having one end connected to the reinforcing member and the other end exposed to an upper surface of the encapsulant; and
a heat dissipation member connected to the connection via and covering the upper surface of the encapsulant.

13. The fan-out semiconductor package of claim 12, wherein a lower surface of the heat dissipation member is in contact with an upper surface of the semiconductor chip.

14. The fan-out semiconductor package of claim 12, wherein the connection via and the heat dissipation member are made of the same material as that of the reinforcing member.

15. The fan-out semiconductor package of claim 12, wherein the connection via has a bar shape corresponding to that of the reinforcing member.

16. The fan-out semiconductor package of claim 1, further comprising:
a plurality of connection vias each having one end connected to the reinforcing member and the other end exposed to an upper surface of the encapsulant, disposed on the reinforcing member to be spaced apart from each other, and each having a pillar shape; and
a heat dissipation member connected to the plurality of connection vias and covering the upper surface of the encapsulant.

17. The fan-out semiconductor package of claim 1, further comprising a second semiconductor chip disposed side by side with the first semiconductor chip in a horizontal direction,
wherein the reinforcing member surrounds the second semiconductor chip, and
the encapsulant embeds the second semiconductor chip.

18. A fan-out semiconductor package comprising:
a redistribution portion;
a first semiconductor chip disposed on an upper surface of the redistribution portion;
a reinforcing member disposed at an edge of the redistribution portion;
an encapsulant disposed on the redistribution portion, an upper surface of the first semiconductor chip being exposed from the encapsulant and the reinforcing member being embedded in the encapsulant;
a connection via connected to the reinforcing member and having one end exposed to an upper surface of the encapsulant; and
a heat dissipation member connected to the connection via and covering the encapsulant to be in contact with the upper surface of the first semiconductor chip.

19. The fan-out semiconductor package of claim 18, further comprising a second semiconductor chip disposed side by side with the first semiconductor chip on the upper surface of the redistribution portion,
wherein an upper surface of the second semiconductor chip is exposed from the encapsulant, and
the heat dissipation member is in contact with the upper surface of the second semiconductor chip.
